(19) United States
(12) Patent Application Publication
(10) Pub. No.: US 2026/0005172 A1
(43) Pub. Date: Jan. 1, 2026

(54) SUBSTRATE STRUCTURE AND MANUFACTURING METHOD THEREOF

(71) Applicant: SILICONWARE PRECISION INDUSTRIES CO., LTD., Taichung City (TW)

(72) Inventors: Meng-Jou HE, Taichung City (TW); Yuan-Ping YEH, Taichung City (TW); Yu-Cheng PAI, Taichung City (TW)

(73) Assignee: SILICONWARE PRECISION INDUSTRIES CO., LTD., Taichung City (TW)

(21) Appl. No.: 18/909,575

(22) Filed: Oct. 8, 2024

(30) Foreign Application Priority Data
Jul. 1, 2024 (TW) 113124544

(51) Int. Cl. H01L 23/00; H01L 23/538

(52) U.S. Cl. CPC H01L 24/09; H01L 23/5383; H01L 23/5384; H01L 2224/06102; H01L 2224/065

(57) ABSTRACT

A substrate structure and a manufacturing method thereof are provided, in which a core layer having first and second connection pads is formed, and first bonding pads of a first circuit build-up layer and second bonding pads of a second circuit build-up layer are respectively bonded to the first connection pads and the second connection pads, so that the first circuit build-up layer and the second circuit build-up layer are respectively located on a first side and a second side of the core layer, and a first gap is formed between the first side and the first circuit build-up layer, and a second gap is formed between the second side and the second circuit build-up layer. Thereby, the core layer and the first and second circuit build-up layers can be manufactured separately and concurrently, thereby shortening the manufacturing process of the substrate structure and improving the yield of the substrate structure.

### BACKGROUND

### 1. Technical Field

The present disclosure relates to a manufacturing technology of a substrate structure, and more particularly, to a substrate structure having a circuit build-up layer and a manufacturing method thereof.

### 2. Description of Related Art

As the number of input/output (I/O) in electronic products increases, the substrate structure (or substrate) needs to increase the number of circuit sub-layers and increase the unit size to provide sufficient layout space.

However, increasing the number of circuit sub-layers in the substrate structure will lengthen the manufacturing process and the delivery time. Moreover, the larger the unit size of the substrate structure, the lower the board utilization rate will be. In addition, the increase in the number of circuit sub-layers in the substrate structure will continue to accumulate defective conditions and will also increase the risk of low yield in the substrate structure.

Furthermore, if unfortunately a batch abnormality in the substrate structure is discovered when the outermost circuit sub-layer of the substrate structure is completed, the substrate structure must be re-produced and the process time will be doubled. In addition, the alignment of the substrate structure will also lead to a greater cumulative offset of the circuit sub-layer or its conductive blind via as the number of circuit sub-layers increases.

FIG. 1A to FIG. 1F are schematic cross-sectional views illustrating a manufacturing method of a substrate structure 1 of the prior art, and the substrate structure 1 may include at least ten layers (such as ten layers, twelve layers, fourteen layers, sixteen layers, or more) of circuit sub-layers.

Taking the production of a substrate structure 1 including ten circuit sub-layers as an example, it is necessary to produce a first circuit build-up layer 20 including five circuit sub-layers and a second circuit build-up layer 30 including five circuit sub-layers, wherein a total of five build-up processes need to be performed, as shown below from the first build-up process to the fifth build-up process.

As shown in FIG. 1A, a core layer 10 having a first side 10a and a second side 10b opposite to the first side 10a is provided.

The first build-up process: as shown in FIG. 1B, a first circuit sub-layer 21 and a second circuit sub-layer 31 are respectively built up to the first side 10a and the second side 10b of the core layer 10.

The second build-up process: as shown in FIG. 1C, a third circuit sub-layer 22 and a fourth circuit sub-layer 32 are respectively built up to the first circuit sub-layer 21 and the second circuit sub-layer 31.

The third build-up process: as shown in FIG. 1D, a fifth circuit sub-layer 23 and a sixth circuit sub-layer 33 are respectively built up to the third circuit sub-layer 22 and the fourth circuit sub-layer 32.

The fourth build-up process: as shown in FIG. 1E, a seventh circuit sub-layer 24 and an eighth circuit sub-layer 34 are respectively built up to the fifth circuit sub-layer 23 and the sixth circuit sub-layer 33.

The fifth build-up process: as shown in FIG. 1F, a ninth circuit sub-layer 25 and a tenth circuit sub-layer 35 are respectively built up to the seventh circuit sub-layer 24 and the eighth circuit sub-layer 34.

Accordingly, the substrate structure 1 including ten circuit sub-layers can be obtained, and the first circuit build-up layer 20 and the second circuit build-up layer 30 of the substrate structure 1 both include five circuit sub-layers. That is, the first circuit build-up layer 20 includes a first circuit sub-layer 21, a third circuit sub-layer 22, a fifth circuit sub-layer 23, a seventh circuit sub-layer 24 and a ninth circuit sub-layer 25, and the second circuit build-up layer 30 includes a second circuit sub-layer 31, a fourth circuit sub-layer 32, a sixth circuit sub-layer 33, an eighth circuit sub-layer 34 and a tenth circuit sub-layer 35.

Assuming that a build-up process will cause a circuit sub-layer of the first circuit build-up layer 20 or the second circuit build-up layer 30 or its conductive blind via to produce an offset of, for example, 25 microns (μm) from the inside to the outside, then five build-up processes will cause five circuit sub-layers of the first circuit build-up layer 20 or the second circuit build-up layer 30 or its conductive blind via to produce a cumulative offset M of, for example, 125 microns (μm) from the inside to the outside.

Furthermore, laminating and manufacturing the circuit sub-layers of the first circuit build-up layer 20 and the second circuit build-up layer 30 layer by layer from the core layer 10 to the outside will cause the process of the substrate structure 1 to be lengthy, and the higher the number of circuit sub-layers of the first circuit build-up layer 20 and the second circuit build-up layer 30, the larger the size of the substrate structure 1 and the higher the risk of low yield.

In addition, when the number of circuit sub-layers of the substrate structure 1 is greater, the number of build-up process of the substrate structure 1 is greater, the process is longer, and the delivery time is longer. This will also cause the alignment of the substrate structure 1 to increase as the number of circuit sub-layer increases, resulting in a greater cumulative offset M of the circuit sub-layer or its conductive blind via, and will also increase the risk of low yield of the substrate structure 1.

Therefore, how to overcome the above-mentioned problems of the prior art has become an urgent issue to be solved.

### SUMMARY

In view of the various deficiencies of the prior art, the present disclosure provides a substrate structure, which comprises: a core layer having a first side, a second side opposite to the first side, a plurality of first connection pads formed on the first side and a plurality of second connection pads formed on the second side; a first circuit build-up layer comprising a plurality of first bonding pads bonded to the plurality of first connection pads of the core layer, wherein the first circuit build-up layer is located on the first side of the core layer, and a first gap is formed between the first side of the core layer and the first circuit build-up layer; and a second circuit build-up layer comprising a plurality of second bonding pads bonded to the plurality of second connection pads of the core layer, wherein the second circuit build-up layer is located on the second side of the core layer, and a second gap is formed between the second side of the core layer and the second circuit build-up layer.

The present disclosure also provides a method of manufacturing a substrate structure, and the method comprises: providing a core layer having a first side, a second side opposite to the first side, a plurality of first connection pads and a plurality of second connection pads, wherein the plurality of first connection pads and the plurality of second connection pads are formed on the first side and the second side respectively; bonding a plurality of first bonding pads of a first circuit build-up layer to the plurality of first connection pads of the core layer, wherein the first circuit build-up layer is located on the first side of the core layer, and a first gap is formed between the first side of the core layer and the first circuit build-up layer; and bonding a plurality of second bonding pads of a second circuit build-up layer to the plurality of second connection pads of the core layer, wherein the second circuit build-up layer is located on the second side of the core layer, and a second gap is formed between the second side of the core layer and the second circuit build-up layer.

In the aforementioned substrate structure, the core layer further has a plurality of conductive vias penetrating through the first side and the second side and electrically connected to the plurality of first connection pads and the plurality of second connection pads.

In the aforementioned substrate structure and method, the first circuit build-up layer and the second circuit build-up layer both include at least five circuit sub-layers, and a number of circuit sub-layers of the first circuit build-up layer is the same as a number of circuit sub-layers of the second circuit build-up layer.

In the aforementioned substrate structure and method, the first circuit build-up layer and the second circuit build-up layer both include at least five circuit sub-layers, and a number of circuit sub-layers of the first circuit build-up layer is different from a number of circuit sub-layers of the second circuit build-up layer.

In the aforementioned substrate structure and method, the substrate structure can include a first cladding layer and a second cladding layer, wherein the first cladding layer is formed in the first gap between the first side of the core layer and the first circuit build-up layer and covers the plurality of first connection pads and the plurality of first bonding pads, and the second cladding layer is formed in the second gap between the second side of the core layer and the second circuit build-up layer and covers the plurality of second connection pads and the plurality of second bonding pads.

In the aforementioned substrate structure and method, the first circuit build-up layer and the second circuit build-up layer further include a first insulating protective sub-layer having a plurality of first openings and a second insulating protective sub-layer having a plurality of second openings respectively, and the first insulating protective sub-layer and the second insulating protective sub-layer are formed on an outermost circuit sub-layer of the first circuit build-up layer and an outermost circuit sub-layer of the second circuit build-up layer respectively.

In the aforementioned substrate structure and method, the substrate structure can include a plurality of first conductors and a plurality of second conductors, wherein the plurality of first bonding pads of the first circuit build-up layer are connected to the plurality of first connection pads of the core layer via the plurality of first conductors, and the plurality of second bonding pads of the second circuit build-up layer are connected to the plurality of second connection pads of the core layer via the plurality of second conductors.

In the aforementioned substrate structure and method, the plurality of first connection pads, the plurality of second connection pads, the plurality of first bonding pads and the plurality of second bonding pads are all made of metal material, wherein the metal material of the plurality of first bonding pads is directly bonded to the metal material of the plurality of first connection pads, and the metal material of the plurality of second bonding pads is directly bonded to the metal material of the plurality of second connection pads.

In the aforementioned substrate structure and method, the first circuit build-up layer and the second circuit build-up layer respectively have a first curved shape and a second curved shape facing in different directions.

In the aforementioned substrate structure and method, the first circuit build-up layer and the second circuit build-up layer respectively have a first curved shape and a second curved shape facing in the same direction.

In the aforementioned method, a first circuit sub-layer of the first circuit build-up layer and a second circuit sub-layer of the second circuit build-up layer are first formed when forming the first circuit build-up layer and the second circuit build-up layer; then, a third circuit sub-layer and a fourth circuit sub-layer of the first circuit build-up layer are respectively built up, stacked, or symmetrically formed on opposite sides of the first circuit sub-layer, and a fifth circuit sub-layer and a sixth circuit sub-layer of the second circuit build-up layer are respectively built up, stacked, or symmetrically formed on opposite sides of the second circuit sub-layer; then, a seventh circuit sub-layer and an eighth circuit sub-layer of the first circuit build-up layer are respectively built up, stacked, or symmetrically formed on the third circuit sub-layer and the fourth circuit sub-layer, and a ninth circuit sub-layer and a tenth circuit sub-layer of the second circuit build-up layer are respectively built up, stacked, or symmetrically formed on the fifth circuit sub-layer and the sixth circuit sub-layer.

As can be seen from the above, in the substrate structure and the manufacturing method thereof of the present disclosure, the substrate structure is divided into a core layer, a first circuit build-up layer and a second circuit build-up layer for concurrent (simultaneous) production, so as to shorten the process or production time of the substrate structure, speed up the delivery time of the substrate structure and improve the manufacturing yield of the substrate structure.

Furthermore, the present disclosure can manufacture the core layer, the first circuit build-up layer and the second circuit build-up layer separately, so as to reduce the number of build-up processes of the first circuit build-up layer and the second circuit build-up layer, and also effectively reduce the cumulative offset of multiple circuit sub-layers or conductive blind vias of the first circuit build-up layer and the second circuit build-up layer.

In addition, the present disclosure can concurrently produce a first circuit build-up layer including at least five circuit sub-layers and a second circuit build-up layer including at least five circuit sub-layers by separate production, concurrent production and/or symmetrical production, so that the more circuit sub-layers of the first circuit build-up layer and the second circuit build-up layer, the more efficacious the build-up process of the substrate structure will be.

### BRIEF DESCRIPTION OF THE DRAWINGS

FIG. 1A to FIG. 1F are schematic cross-sectional views illustrating a conventional method for manufacturing a substrate structure.

FIG. 2A to FIG. 2H are schematic cross-sectional views illustrating a manufacturing method of a substrate structure according to the present disclosure.

FIG. 3 is another schematic cross-sectional view of the substrate structure according to the present disclosure.

FIG. 4A to FIG. 4D are simplified schematic views of the substrate structure according to different embodiments of the present disclosure.

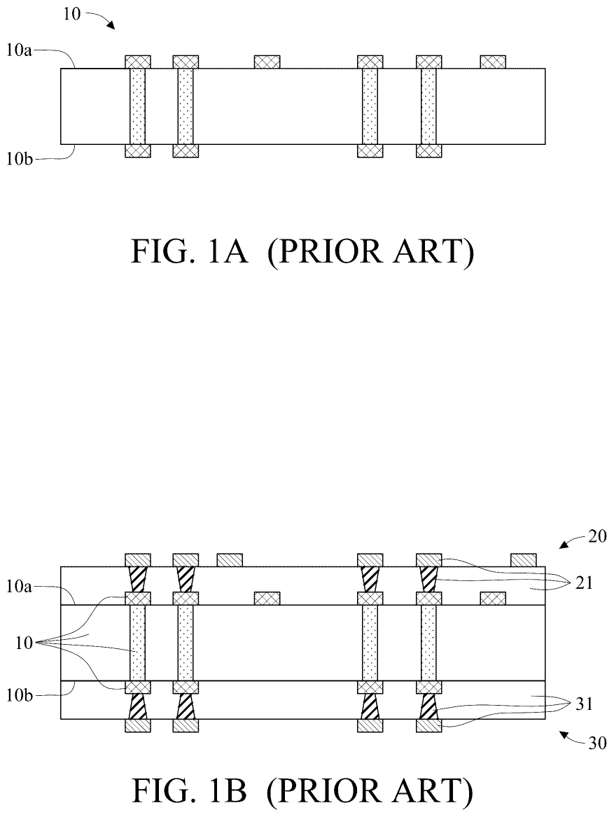

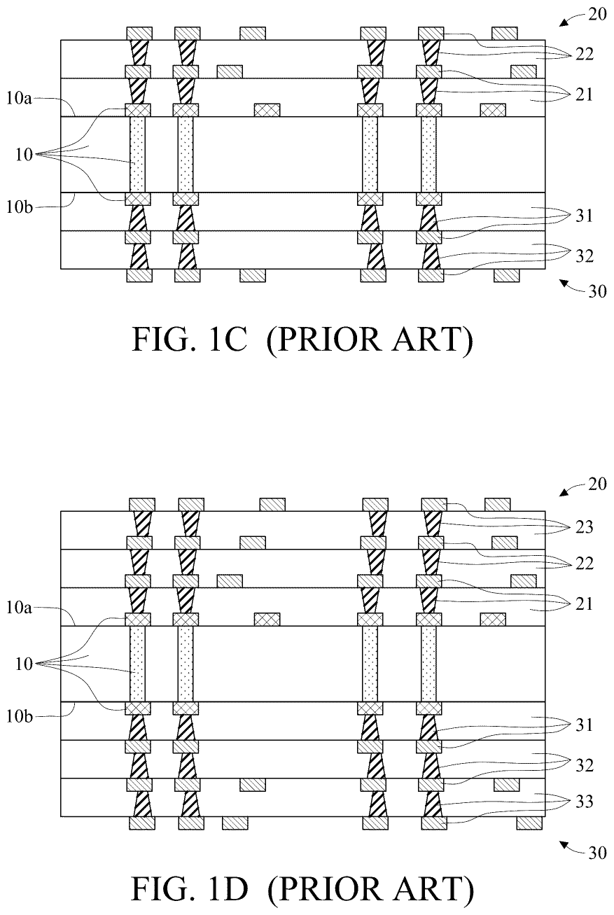

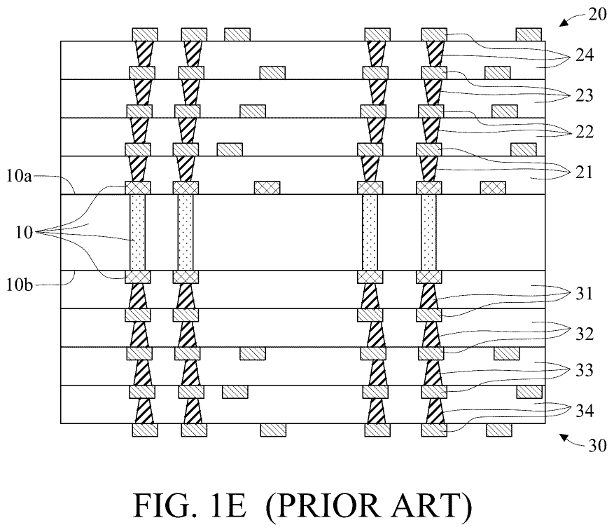

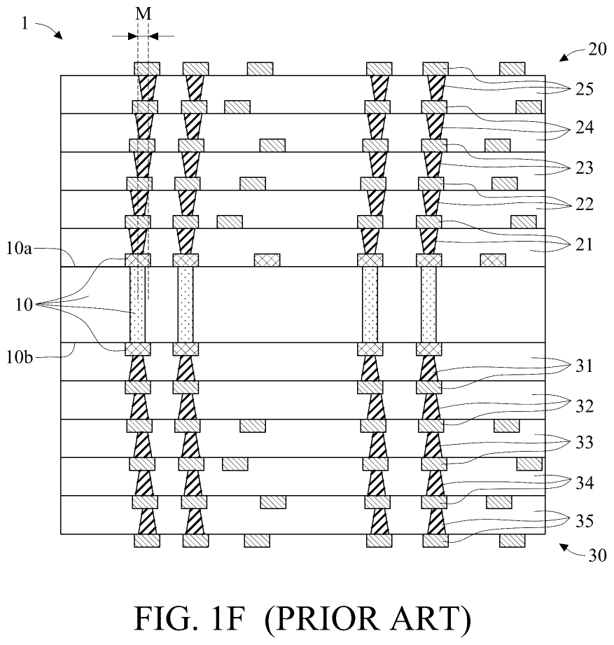

### DETAILED DESCRIPTION

The following describes the implementation of the present disclosure with examples. Those skilled in the art can easily understand other advantages and effects of the present disclosure from the contents disclosed in this specification.

It should be understood that, the structures, ratios, sizes, and the like in the accompanying figures are used for illustrative purposes to facilitate the perusal and comprehension of the contents disclosed in the present specification by one skilled in the art, rather than to limit the conditions for practicing the present disclosure. Any modification of the structures, alteration of the ratio relationships, or adjustment of the sizes without affecting the possible effects and achievable proposes should still be deemed as falling within the scope defined by the technical contents disclosed in the present specification. Meanwhile, terms such as “upper,” “lower,” “a,” “one,” “two,” “first,” “second,” “third” and the like used herein are merely used for clear explanation rather than limiting the practicable scope of the present disclosure, and thus, alterations or adjustments of the relative relationships thereof without essentially altering the technical contents should still be considered in the practicable scope of the present disclosure.

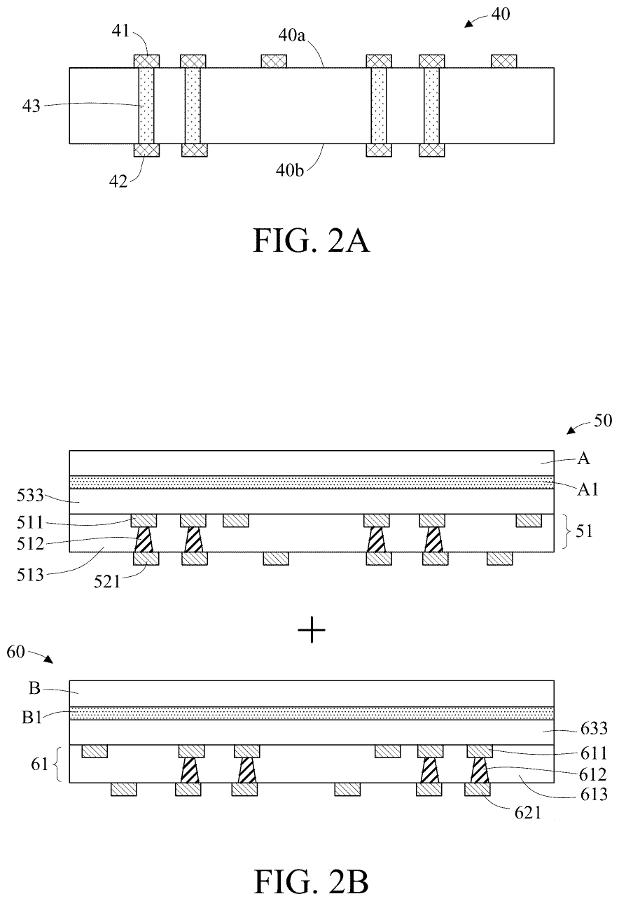

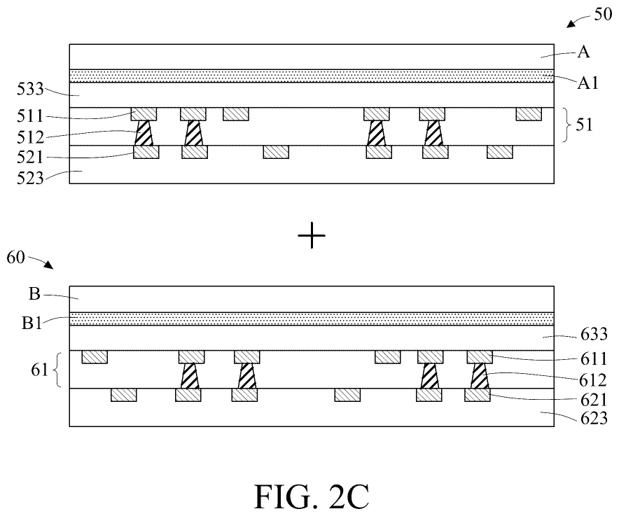

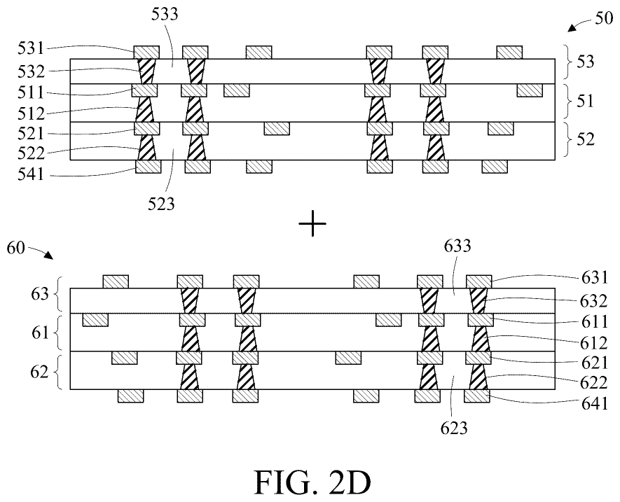

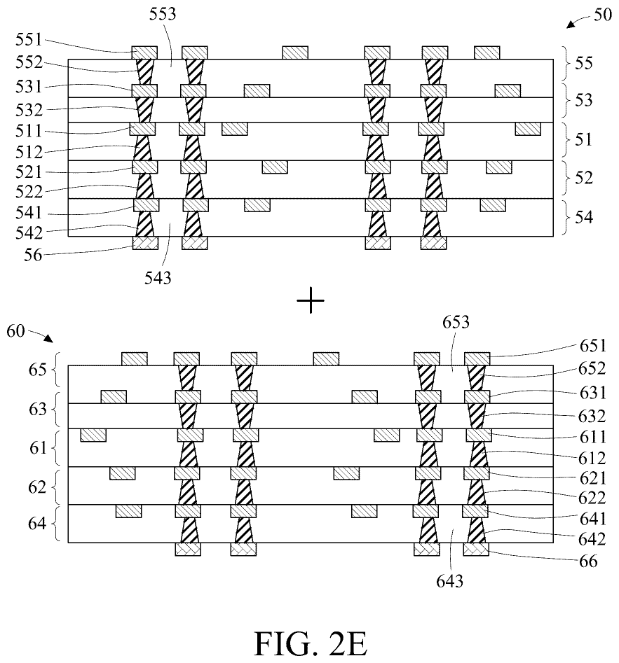

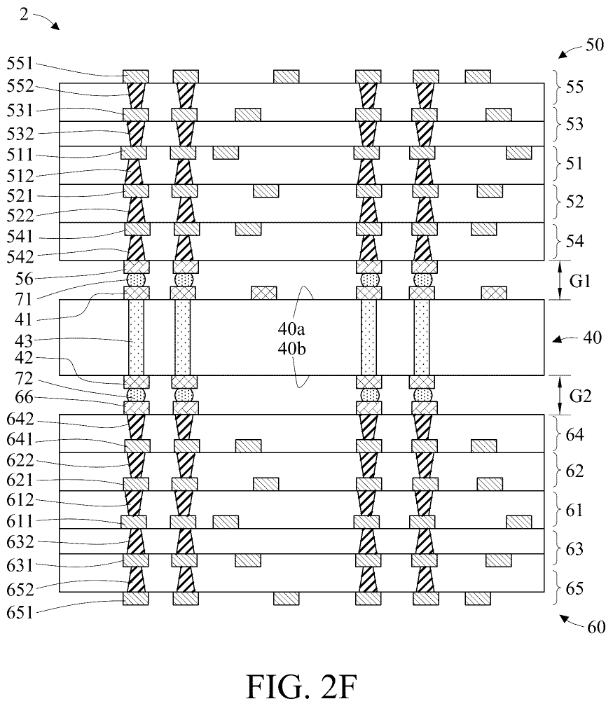

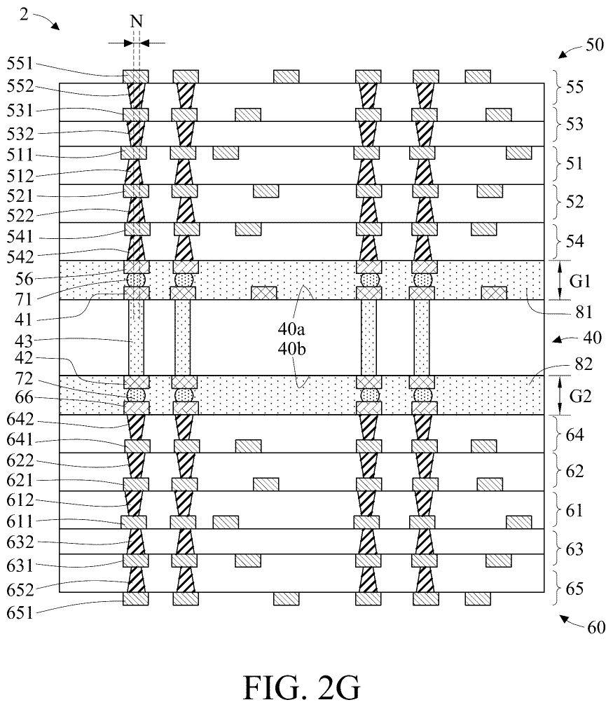

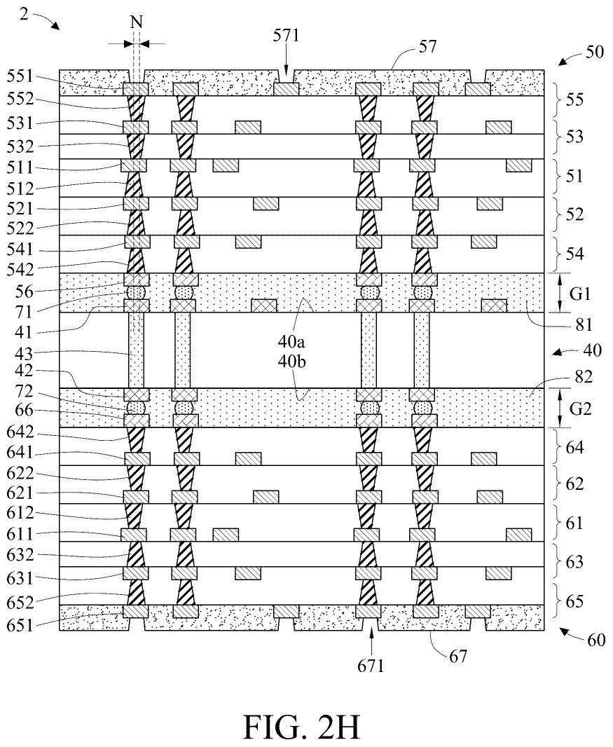

FIG. 2A to FIG. 2H are schematic cross-sectional views illustrating a manufacturing method of a substrate structure 2 according to the present disclosure. The substrate structure 2 may include a core layer 40, a first circuit build-up layer 50 and a second circuit build-up layer 60, and the first circuit build-up layer 50 and the second circuit build-up layer 60 may include the same number of circuit sub-layers or different numbers of circuit sub-layers.

For example, the substrate structure 2 may include at least ten layers (such as ten layers, twelve layers, fourteen layers, sixteen layers, or more) of circuit sub-layers, and both the first circuit build-up layer 50 and the second circuit build-up layer 60 of the substrate structure 2 may include at least five layers (such as five layers, seven layers, nine layers, or more) of circuit sub-layers.

Taking the production of the substrate structure 2 including ten circuit sub-layers as an example, it is necessary to produce a first circuit build-up layer 50 including five circuit sub-layers and a second circuit build-up layer 60 including five circuit sub-layers. However, the present disclosure only needs to perform three build-up processes, that is, the following first build-up process to the third build-up process.

As shown in FIG. 2A, a core layer 40 having a first side 40a, a second side 40b opposite to the first side 40a, a plurality of first connection pads 41, a plurality of second connection pads 42 and a plurality of conductive vias 43 is provided, wherein the plurality of first connection pads 41 and the plurality of second connection pads 42 of the core layer 40 may be formed on the first side 40a and the second side 40b respectively, and the plurality of conductive vias 43 can penetrate through the first side 40a and the second side 40b of the core layer 40 to be electrically connected to the plurality of first connection pads 41 and the plurality of second connection pads 42.

In one embodiment, the substrate structure 2 can be a semiconductor substrate structure or the like, the body or core part of the core layer 40 can be a core board, and each of the first connection pads 41 or each of the second connection pads 42 can be a bonding pad, a metal pad, a conductive pad, or the like, wherein the material of each of the first connection pads 41 or each of the second connection pads 42 may be a metal material or a conductive material, and each of the conductive vias 43 may be a through-silicon via, but the present disclosure is not limited to as such.

The first build-up process: a first circuit sub-layer 51 and a second circuit sub-layer 61 are respectively built up or stacked on a first carrier A and a second carrier B concurrently.

As shown in FIG. 2B, a first carrier A having a first release film A1 is provided, so that a first circuit sub-layer 51 is built up or stacked on the first release film A1 of the first carrier A. Meanwhile, a second carrier B having a second release film B1 is provided, so that a second circuit sub-layer 61 is built up or stacked on the second release film B1 of the second carrier B. For example, the first carrier A and the second carrier B are both removable carriers, carrier plates, or the like, and the first release film A1 or the second release film B1 can be a film coated with a release agent, etc.

In one embodiment, the first circuit sub-layer 51 may have at least one first circuit 511, a plurality of first conductive blind vias 512, a first dielectric material 513, etc., wherein the plurality of first conductive blind vias 512 can be electrically connected to the first circuit 511, and the first dielectric material 513 can be bonded to the first circuit 511 and the plurality of first conductive blind vias 512. Meanwhile, the second circuit sub-layer 61 has at least one second circuit 611, a plurality of second conductive blind vias 612, a second dielectric material 613, etc., wherein the plurality of second conductive blind vias 612 can be electrically connected to the second circuit 611, and the second dielectric material 613 can be bonded to the second circuit 611 and the plurality of second conductive blind vias 612.

In one embodiment, at least a third circuit 521 and a fourth dielectric material 533 can be formed on opposite sides of the first circuit sub-layer 51, respectively, wherein the fourth dielectric material 533 may be located between the first release film A1 of the first carrier A and the first circuit sub-layer 51, and the third circuit 521 may be electrically connected to the plurality of first conductive blind vias 512. Meanwhile, at least a fifth circuit 621 and a sixth dielectric material 633 can be formed on opposite sides of the second circuit sub-layer 61 respectively, wherein the sixth dielectric material 633 may be located between the second release film B1 of the second carrier B and the second circuit sub-layer 61, and the fifth circuit 621 may be electrically connected to the plurality of second conductive blind vias 612.

As shown in FIG. 2C, a third dielectric material 523 is formed on the third circuit 521 to be bonded to (cover) the third circuit 521, and a fifth dielectric material 623 is formed on the fifth circuit 621 to be bonded to (cover) the fifth circuit 621.

The second build-up process: mainly, a third circuit sub-layer 52 and a fourth circuit sub-layer 53 can be concurrently built up, stacked, or symmetrically formed on the opposite sides of the first circuit sub-layer 51, and a fifth circuit sub-layer 62 and a sixth circuit sub-layer 63 can be concurrently built up, stacked, or symmetrically formed on opposite sides of the second circuit sub-layer 61.

As shown in FIG. 2D, a plurality of third conductive blind vias 522 are formed in the third dielectric material 523 to be electrically connected to the third circuit 521, so that the third circuit 521, the plurality of third conductive blind vias 522 and the third dielectric material 523 form a third circuit sub-layer 52. Furthermore, the first carrier A and the first release film A1 thereof in FIG. 2C are removed to expose the fourth dielectric material 533, and a plurality of fourth conductive blind vias 532 are also formed in the fourth dielectric material 533. Then, at least one fourth circuit 531 is formed on the fourth dielectric material 533 to be electrically connected to the plurality of fourth conductive blind vias 532, so that the fourth circuit 531, the plurality of fourth conductive blind vias 532 and the fourth dielectric material 533 form a fourth circuit sub-layer 53.

Meanwhile, a plurality of fifth conductive blind vias 622 are formed in the fifth dielectric material 623 to be electrically connected to the fifth circuit 621, so that the fifth circuit 621, the plurality of fifth conductive blind vias 622 and the fifth dielectric material 623 form a fifth circuit sub-layer 62. Moreover, the second carrier B and the second release film B1 thereof in FIG. 2C are removed to expose the sixth dielectric material 633, and a plurality of sixth conductive blind vias 632 are also formed in the sixth dielectric material 633. Then, at least one sixth circuit 631 is formed on the sixth dielectric material 633 to be electrically connected to the plurality of sixth conductive blind vias 632, so that the sixth circuit 631, the plurality of sixth conductive blind vias 632 and the sixth dielectric material 633 form a sixth circuit sub-layer 63.

In one embodiment, at least one seventh circuit 541 can be formed on the third dielectric material 523 of the third circuit sub-layer 52 to be electrically connected to the plurality of third conductive blind vias 522, and at least one ninth circuit 641 may be formed on the fifth dielectric material 623 of the fifth circuit sub-layer 62 to be electrically connected to the plurality of fifth conductive blind vias 622.

The third build-up process: mainly, a seventh circuit sub-layer 54 and an eighth circuit sub-layer 55 can be concurrently built up, stacked, or symmetrically formed on the third circuit sub-layer 52 and the fourth circuit sub-layer 53, and a ninth circuit sub-layer 64 and a tenth circuit sub-layer 65 can be concurrently built up, stacked, or symmetrically formed on the fifth circuit sub-layer 62 and the sixth circuit sub-layer 63.

As shown in FIG. 2E, a seventh dielectric material 543 is formed on the third circuit sub-layer 52 to be bonded to (cover) the seventh circuit 541, and then a plurality of seventh conductive blind vias 542 are formed in the seventh dielectric material 543 to be electrically connected to the seventh circuit 541, so that the seventh circuit 541, the plurality of seventh conductive blind vias 542 and the seventh dielectric material 543 form a seventh circuit sub-layer 54. Furthermore, an eighth dielectric material 553 is formed on the fourth circuit sub-layer 53 to be bonded to (cover) the fourth circuit 531, a plurality of eighth conductive blind vias 552 are also formed in the eighth dielectric material 553 to be electrically connected to the fourth circuit 531, and at least one eighth circuit 551 is then formed on the eighth dielectric material 553 to be electrically connected to the plurality of eighth conductive blind vias 552, so that the eighth circuit 551, the plurality of eighth conductive blind vias 552 and the eighth dielectric material 553 form an eighth circuit sub-layer 55.

Meanwhile, a ninth dielectric material 643 is formed on the fifth circuit sub-layer 62, and a plurality of ninth conductive blind vias 642 are formed in the ninth dielectric material 643 to be electrically connected to the ninth circuit 641, so that the ninth circuit 641, the plurality of ninth conductive blind vias 642 and the ninth dielectric material 643 form a ninth circuit sub-layer 64. Furthermore, a tenth dielectric material 653 is formed on the sixth circuit sub-layer 63, a plurality of tenth conductive blind vias 652 are also formed in the tenth dielectric material 653 to be electrically connected to the sixth circuit 631, and then at least one tenth circuit 651 is formed on the tenth dielectric material 653, so that the tenth circuit 651, the plurality of tenth conductive blind vias 652 and the tenth dielectric material 653 form a tenth circuit sub-layer 65.

Thus, via the above three build-up processes (i.e., the first build-up process to the third build-up process) of the present disclosure, the first circuit sub-layer 51, the third circuit sub-layer 52, the fourth circuit sub-layer 53, the seventh circuit sub-layer 54 and the eighth circuit sub-layer 55 form a first circuit build-up layer 50, and the second circuit sub-layer 61, the fifth circuit sub-layer 62, the sixth circuit sub-layer 63, the ninth circuit sub-layer 64 and the tenth circuit sub-layer 65 form a second circuit build-up layer 60.

Furthermore, in the first circuit build-up layer 50 and the second circuit build-up layer 60 of the present disclosure, a plurality of first bonding pads 56 may also be formed on the seventh circuit sub-layer 54 to be electrically connected to the plurality of seventh conductive blind vias 542, and meanwhile, a plurality of second bonding pads 66 are formed on the ninth circuit sub-layer 64 to be electrically connected to the plurality of ninth conductive blind vias 642.

In one embodiment, the first dielectric material 513 to the tenth dielectric material 653 may be insulating materials or the like, wherein each of the first bonding pads 56 or each of the second bonding pads 66 may be a connection pad, a metal pad, a conductive pad, or the like, and the material of each of the first bonding pads 56 or each of the second bonding pads 66 may be a metal material, a conductive material, or the like.

In addition, if the plurality of first circuit build-up layers 50 and the plurality of second circuit build-up layers 60 are completed at one time or in batches, the present disclosure can also screen out the first circuit build-up layer 50 and the second circuit build-up layer 60 with higher yield to be bonded to the core layer 40 to improve the yield of the substrate structure 2 and thereby reduce the risk of low yield.

As shown in FIG. 2F, after forming the first circuit build-up layer 50 and the second circuit build-up layer 60, the first circuit build-up layer 50 and the second circuit build-up layer 60 are bonded to the first side 40a and the second side 40b of the core layer 40, respectively.

In one embodiment, the plurality of first bonding pads 56 of the first circuit build-up layer 50 can be bonded to the plurality of first connection pads 41 of the core layer 40, and the plurality of second bonding pads 66 of the second circuit build-up layer 60 can be bonded to the plurality of second connection pads 42 of the core layer 40. Meanwhile, there may be a first gap G1 between the first circuit build-up layer 50 (such as the seventh circuit sub-layer 54) and the first side 40a of the core layer 40, and there may be a second gap G2 between the second circuit build-up layer 60 (such as the ninth circuit sub-layer 64) and the second side 40b of the core layer 40.

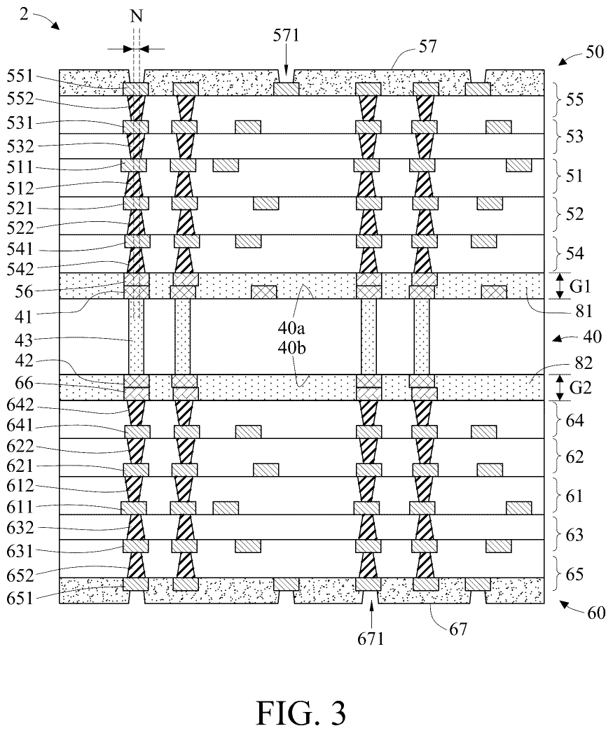

In one embodiment, the plurality of first bonding pads 56 of the first circuit build-up layer 50 can be bonded or electrically connected to the plurality of first connection pads 41 of the core layer 40 via the plurality of first conductors 71, and the plurality of second bonding pads 66 of the second circuit build-up layer 60 can be bonded or electrically connected to the plurality of second connection pads 42 of the core layer 40 via the plurality of second conductors 72. However, in other embodiments (see FIG. 3), the plurality of first bonding pads 56 of the first circuit build-up layer 50 can also be directly bonded or electrically connected to the plurality of first connection pads 41 of the core layer 40, and the plurality of second bonding pads 66 of the second circuit build-up layer 60 may also be directly bonded or electrically connected to the plurality of second connection pads 42 of the core layer 40.

As shown in FIG. 2G, a first cladding layer 81 is formed in the first gap G1 between the first side 40a of the core layer 40 and the first circuit build-up layer 50 (such as the seventh circuit sub-layer 54) to cover the plurality of first connection pads 41 of the core layer 40, the plurality of first bonding pads 56 of the first circuit build-up layer 50, and the plurality of first conductors 71, and a second cladding layer 82 is formed in the second gap G2 between the second side 40b of the core layer 40 and the second circuit build-up layer 60 (such as the ninth circuit sub-layer 64) to cover the plurality of second connection pads 42 of the core layer 40, the plurality of second bonding pads 66 of the second circuit build-up layer 60 and the plurality of second conductors 72.

In one embodiment, each of the first conductors 71 or each of the second conductors 72 can be a conductive element, a conductive bump, a metal ball (such as a tin ball), a solder ball, or the like, and the first cladding layer 81 or the second cladding layer 82 may be an encapsulation layer, a filling layer, an underfill, or the like.

In addition, it is assumed that a build-up process will cause a circuit sub-layer of the first circuit build-up layer 50 or the second circuit build-up layer 60 or its conductive blind via to produce an offset (or displacement) of, for example, 25 micrometers (μm) from the inside to the outside, then three build-up processes of the present disclosure will only cause the five circuit sub-layers of the first circuit build-up layer 50 or the second circuit build-up layer 60 or their conductive blind vias to produce a total cumulative offset N of, for example, 75 micrometers (μm) from the inside to the outside. However, the five build-up processes of the prior art will cause the five circuit sub-layers or their conductive blind vias to produce a total cumulative offset of, for example, 125 microns (μm) from the inside to the outside. Therefore, the cumulative offset N of the three build-up processes of the present disclosure will be significantly less than the cumulative offset of the five build-up processes of the prior art.

As shown in FIG. 2H, the first circuit build-up layer 50 and the second circuit build-up layer 60 may respectively include a first insulating protective sub-layer 57 having a plurality of first openings 571 and a second insulating protective sub-layer 67 having a plurality of second openings 671.

That is, the first insulating protective sub-layer 57 can be formed on the eighth circuit sub-layer 55 (such as the outermost circuit sub-layer) of the first circuit build-up layer 50, and parts of the eighth circuit 551 of the eighth circuit sub-layer 55 are exposed from the plurality of first openings 571 of the first insulating protective sub-layer 57. Meanwhile, a second insulating protective sub-layer 67 can be formed on the tenth circuit sub-layer 65 (such as the outermost circuit sub-layer) of the second circuit build-up layer 60, and parts of the tenth circuit 651 of the tenth circuit sub-layer 65 are exposed from the plurality of second openings 671 of the second insulating protective sub-layer 67.

FIG. 3 is another schematic cross-sectional view of the substrate structure 2 of the present disclosure, and the main differences between FIG. 3 and the substrate structure 2 of FIG. 2 will be described below. The remaining technical content is the same as the detailed description of FIG. 2A to FIG. 2H and will not be repeated here.

In FIG. 3, the plurality of first bonding pads 56 of the first circuit build-up layer 50 can be directly bonded or electrically connected to the plurality of first connection pads 41 of the core layer 40, and the plurality of second bonding pads 66 of the second circuit build-up layer 60 can be directly bonded or electrically connected to the plurality of second connection pads 42 of the core layer 40.

For example, the plurality of first connection pads 41, the plurality of second connection pads 42, the plurality of first bonding pads 56 and the plurality of second bonding pads 66 all have metal materials, so that the metal material of the plurality of first bonding pads 56 is directly bonded to the metal material of the plurality of first connection pads 41 via metal-to-metal bonding, and the metal material of the plurality of second bonding pads 66 is directly bonded to the metal material of the plurality of second connection pads 42 via metal-to-metal bonding, thereby eliminating the first conductors 71 and the second conductors 72 in FIG. 2H.

It should be noted that in the above-mentioned embodiments of FIG. 2A to FIG. 2H and FIG. 3, the substrate structure 2 of the present disclosure includes ten circuit sub-layers, and for example, the first circuit build-up layer 50 and the second circuit build-up layer 60 of the substrate structure 2 both include the same number of circuit sub-layers (such as five circuit sub-layers). However, in other embodiments, the substrate structure 2 may also include fewer or more layers (such as twelve layers, fourteen layers, sixteen layers, or more) of circuit sub-layers, and the first circuit build-up layer 50 and the second circuit build-up layer 60 of the substrate structure 2 may also include different numbers of circuit sub-layers.

For example, the substrate structure 2 may include twelve circuit sub-layers, and the first circuit build-up layer 50 and the second circuit build-up layer 60 of the substrate structure 2 respectively include different numbers of five circuit sub-layers and seven circuit sub-layers. Alternatively, the substrate structure 2 may include fourteen circuit sub-layers, and the first circuit build-up layer 50 and the second circuit build-up layer 60 of the substrate structure 2 both include the same number of seven circuit sub-layers. Alternatively, the substrate structure 2 may include sixteen circuit sub-layers, and the first circuit build-up layer 50 and the second circuit build-up layer 60 respectively include different numbers of nine circuit sub-layers and seven circuit sub-layers.

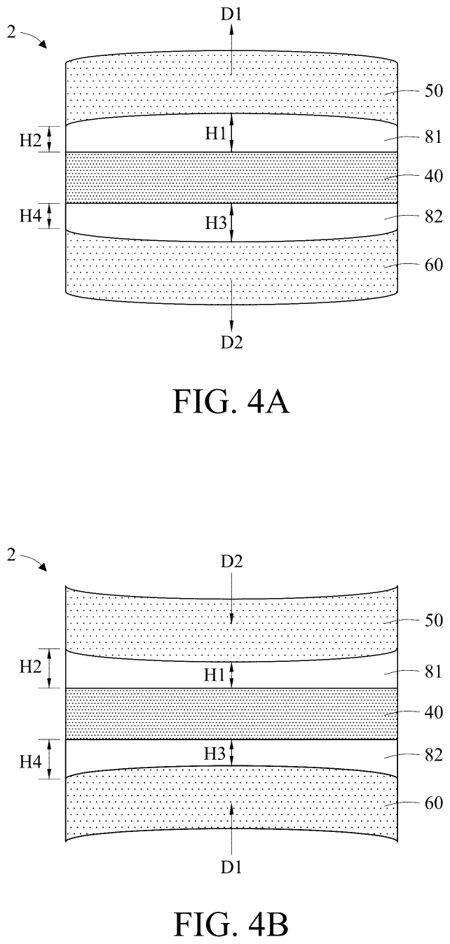

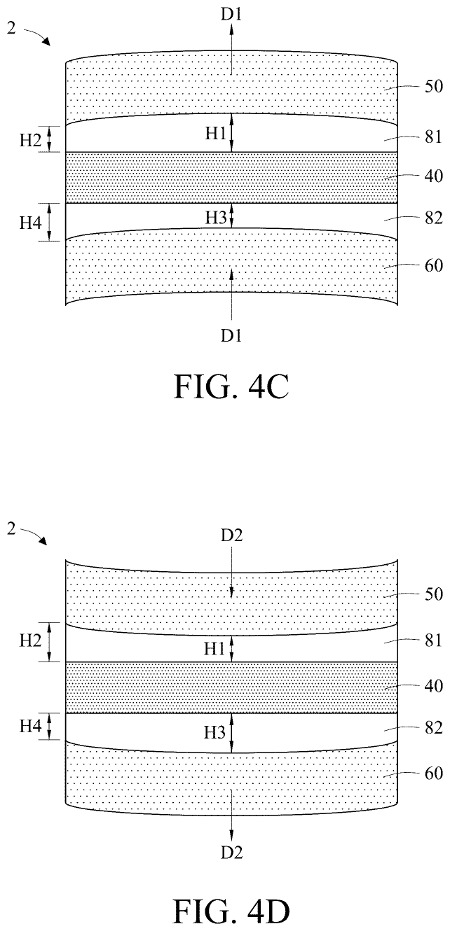

FIG. 4A to FIG. 4D are simplified schematic views of different embodiments of the substrate structure 2 of the present disclosure. Meanwhile, the first circuit build-up layer 50 and the second circuit build-up layer 60 of the substrate structure 2 may respectively have a first deformation tendency and a second deformation tendency. For example, the first circuit build-up layer 50 and the second circuit build-up layer 60 may have a first curved shape and a second curved shape facing different directions, respectively. Alternatively, the first circuit build-up layer 50 and the second circuit build-up layer 60 may respectively have a first curved shape and a second curved shape facing the same direction.

As shown in the embodiment of FIG. 4A, the first circuit build-up layer 50 may have a first curved shape toward the first direction D1 (e.g., an upward direction), and the second circuit build-up layer 60 may have a second curved shape oriented toward a second direction D2 that is different from the first direction D1 (e.g., a downward direction). Meanwhile, the first distance H1 at the center of the first circuit build-up layer 50 and the core layer 40 is greater than the second distance H2 at the edges of the first circuit build-up layer 50 and the core layer 40, and the third distance H3 at the center of the second circuit build-up layer 60 and the core layer 40 is greater than the fourth distance H4 at the edges of the second circuit build-up layer 60 and the core layer 40.

As shown in the embodiment of FIG. 4B, the first circuit build-up layer 50 may have a first curved shape toward the second direction D2 (e.g., a downward direction), and the second circuit build-up layer 60 may have a second curved shape toward the first direction D1 (e.g., an upward direction) different from the second direction D2. Meanwhile, the first distance H1 at the center of the first circuit build-up layer 50 and the core layer 40 is less than the second distance H2 at the edges of the first circuit build-up layer 50 and the core layer 40, and the third distance H3 at the center of the second circuit build-up layer 60 and the core layer 40 is less than the fourth distance H4 at the edges of the second circuit build-up layer 60 and the core layer 40.

As shown in the embodiment of FIG. 4C, the first circuit build-up layer 50 may have a first curved shape toward the first direction D1 (e.g., an upward direction), and the second circuit build-up layer 60 may have a second curved shape facing the same first direction D1 (e.g., an upward direction). Meanwhile, the first distance H1 at the center of the first circuit build-up layer 50 and the core layer 40 is greater than the second distance H2 at the edges of the first circuit build-up layer 50 and the core layer 40, and the third distance H3 at the center of the second circuit build-up layer 60 and the core layer 40 is less than the fourth distance H4 at the edges of the second circuit build-up layer 60 and the core layer 40.

As shown in the embodiment of FIG. 4D, the first circuit build-up layer 50 may have a first curved shape toward the second direction D2 (e.g., a downward direction), and the second circuit build-up layer 60 may have a second curved shape facing the same second direction D2 (e.g., a downward direction). Meanwhile, the first distance H1 at the center of the first circuit build-up layer 50 and the core layer 40 is less than the second distance H2 at the edges of the first circuit build-up layer 50 and the core layer 40, and the third distance H3 at the center of the second circuit build-up layer 60 and the core layer 40 is greater than the fourth distance H4 at the edges of the second circuit build-up layer 60 and the core layer 40.

The present disclosure also provides a substrate structure 2, which comprises: a core layer 40 having a first side 40a, a second side 40b opposite to the first side 40a, a plurality of first connection pads 41 and a plurality of second connection pads 42, wherein the plurality of first connection pads 41 and the plurality of second connection pads 42 of the core layer 40 are formed on the first side 40a and the second side 40b respectively; a first circuit build-up layer 50 including a plurality of first bonding pads 56 bonded to the plurality of first connection pads 41 of the core layer 40, wherein the first circuit build-up layer 50 is located on the first side 40a of the core layer 40, and a first gap G1 is formed between the first side 40a of the core layer 40 and the first circuit build-up layer 50; and a second circuit build-up layer 60 including a plurality of second bonding pads 66 bonded to the plurality of second connection pads 42 of the core layer 40, wherein the second circuit build-up layer 60 is located on the second side 40b of the core layer 40, and a second gap G2 is formed between the second side 40b of the core layer 40 and the second circuit build-up layer 60.

In one embodiment, the core layer 40 may have a plurality of conductive vias 43 that penetrate through the first side 40a and the second side 40b of the core layer 40 to be electrically connected to the plurality of first connection pads 41 and the plurality of second connection pads 42.

In one embodiment, both the first circuit build-up layer 50 and the second circuit build-up layer 60 include at least five circuit sub-layers, and the number of circuit sub-layers of the first circuit build-up layer 50 is the same as the number of circuit sub-layers of the second circuit build-up layer 60.

In one embodiment, both the first circuit build-up layer 50 and the second circuit build-up layer 60 include at least five circuit sub-layers, and the number of circuit sub-layers of the first circuit build-up layer 50 is different from the number of circuit sub-layers of the second circuit build-up layer 60.

In one embodiment, the substrate structure 2 may include a first cladding layer 81 and a second cladding layer 82, wherein the first cladding layer 81 is formed in the first gap G1 between the first side 40a of the core layer 40 and the first circuit build-up layer 50 to cover the plurality of first connection pads 41 and the plurality of first bonding pads 56, and the second cladding layer 82 is formed in the second gap G2 between the second side 40b of the core layer 40 and the second circuit build-up layer 60 to cover the plurality of second connection pads 42 and the plurality of second bonding pads 66.

In one embodiment, the first circuit build-up layer 50 and the second circuit build-up layer 60 may respectively include a first insulating protective sub-layer 57 having a plurality of first openings 571 and a second insulating protective sub-layer 67 having a plurality of second openings 671, and the first insulating protective sub-layer 57 and the second insulating protective sub-layer 67 are respectively formed on the outermost circuit sub-layer of the first circuit build-up layer 50 and the outermost circuit sub-layer of the second circuit build-up layer 60.

In one embodiment, the substrate structure 2 may include a plurality of first conductors 71 and a plurality of second conductors 72, wherein the plurality of first bonding pads 56 of the first circuit build-up layer 50 are connected to the plurality of first connection pads 41 of the core layer 40 via the plurality of first conductors 71, and the plurality of second bonding pads 66 of the second circuit build-up layer 60 are connected to the plurality of second connection pads 42 of the core layer 40 via the plurality of second conductors 72.

In one embodiment, the plurality of first connection pads 41, the plurality of second connection pads 42, the plurality of first bonding pads 56 and the plurality of second bonding pads 66 are all made of metal material, wherein the metal material of the plurality of first bonding pads 56 is directly bonded to the metal material of the plurality of first connection pads 41, and the metal material of the plurality of second bonding pads 66 is directly bonded to the metal material of the plurality of second connection pads 42.

In one embodiment, the first circuit build-up layer 50 and the second circuit build-up layer 60 respectively have a first curved shape and a second curved shape facing in different directions.

In one embodiment, the first circuit build-up layer 50 and the second circuit build-up layer 60 respectively have a first curved shape and a second curved shape facing the same direction.

In summary, the substrate structure 2 and the manufacturing method thereof of the present disclosure have at least the following features, advantages, or technical effects.
1. The present disclosure can divide the substrate structure 2 into the core layer 40, the first circuit build-up layer 50 and the second circuit build-up layer 60 for concurrent (simultaneous) production, so as to shorten the process or production time of the substrate structure 2, speed up the delivery time of the substrate structure 2, and improve the production yield of the substrate structure 2.
2. The present disclosure can produce the core layer 40, the first circuit build-up layer 50 and the second circuit build-up layer 60 separately, so as to facilitate reducing the number of build-up processes of the first circuit build-up layer 50 and the second circuit build-up layer 60, and also effectively reduce the cumulative offset N (such as stacking cumulative offset) of multiple circuit sub-layers or conductive blind vias of the first circuit build-up layer 50 and the second circuit build-up layer 60.
3. The present disclosure can concurrently produce the first circuit build-up layer 50 including at least five circuit sub-layers and the second circuit build-up layer 60 including at least five circuit sub-layers by separate production, concurrent production and/or symmetrical production, so that the greater the number of circuit sub-layers of the first circuit build-up layer 50 and the second circuit build-up layer 60, the greater the efficacy of the build-up process of the substrate structure 2 will be.
4. The present disclosure can bond the first circuit build-up layer 50 and the second circuit build-up layer 60 having a higher yield to the core layer 40 when the plurality of first circuit build-up layers 50 and second circuit build-up layers 60 are completed, so as to improve the yield of the substrate structure 2, thereby reducing the risk of low yield.
5. Taking the production of a substrate structure 2 including ten circuit sub-layers as an example (such as a first circuit build-up layer 50 including five circuit sub-layers and a second circuit build-up layer 60 including five circuit sub-layers), the present disclosure only needs to perform three build-up processes in total, but the prior art requires five build-up processes. Therefore, the present disclosure can effectively reduce the number of build-up processes of the substrate structure 2, and can also shorten the process or production time of the substrate structure 2. Also, the present disclosure can reduce the cumulative offset N (such as stacking cumulative offset) of multiple circuit sub-layers or conductive blind vias of the first circuit build-up layer 50 or the second circuit build-up layer 60.

The foregoing embodiments are provided for the purpose of illustrating the principles and effects of the present disclosure, rather than limiting the present disclosure. Anyone skilled in the art can modify and alter the above embodiments without departing from the spirit and scope of the present disclosure. Therefore, the scope of protection with regard to the present disclosure should be as defined in the accompanying claims listed below.

What is claimed is:

1. A substrate structure, comprising:
a core layer having a first side, a second side opposite to the first side, a plurality of first connection pads formed on the first side and a plurality of second connection pads formed on the second side;
a first circuit build-up layer comprising a plurality of first bonding pads bonded to the plurality of first connection pads of the core layer, wherein the first circuit build-up layer is located on the first side of the core layer, and a first gap is formed between the first side of the core layer and the first circuit build-up layer; and
a second circuit build-up layer comprising a plurality of second bonding pads bonded to the plurality of second connection pads of the core layer, wherein the second circuit build-up layer is located on the second side of the core layer, and a second gap is formed between the second side of the core layer and the second circuit build-up layer.

2. The substrate structure of claim 1, wherein the core layer further has a plurality of conductive vias penetrating through the first side and the second side and electrically connected to the plurality of first connection pads and the plurality of second connection pads.

3. The substrate structure of claim 1, wherein a number of circuit sub-layers of the first circuit build-up layer is the same as a number of circuit sub-layers of the second circuit build-up layer.

4. The substrate structure of claim 1, wherein a number of circuit sub-layers of the first circuit build-up layer is different from a number of circuit sub-layers of the second circuit build-up layer.

5. The substrate structure of claim 1, further comprising a first cladding layer and a second cladding layer, wherein the first cladding layer is formed in the first gap between the first side of the core layer and the first circuit build-up layer and covers the plurality of first connection pads and the plurality of first bonding pads, and the second cladding layer is formed in the second gap between the second side of the core layer and the second circuit build-up layer and covers the plurality of second connection pads and the plurality of second bonding pads.

6. The substrate structure of claim 1, wherein the first circuit build-up layer and the second circuit build-up layer further include a first insulating protective sub-layer having a plurality of first openings and a second insulating protective sub-layer having a plurality of second openings respectively, and the first insulating protective sub-layer and the second insulating protective sub-layer are formed on an outermost circuit sub-layer of the first circuit build-up layer and an outermost circuit sub-layer of the second circuit build-up layer respectively.

7. The substrate structure of claim 1, further comprising a plurality of first conductors and a plurality of second conductors, wherein the plurality of first bonding pads of the first circuit build-up layer are connected to the plurality of first connection pads of the core layer via the plurality of first conductors, and the plurality of second bonding pads of the second circuit build-up layer are connected to the plurality of second connection pads of the core layer via the plurality of second conductors.

8. The substrate structure of claim 1, wherein the plurality of first connection pads, the plurality of second connection pads, the plurality of first bonding pads and the plurality of second bonding pads are all made of metal material, wherein the metal material of the plurality of first bonding pads is directly bonded to the metal material of the plurality of first connection pads, and the metal material of the plurality of second bonding pads is directly bonded to the metal material of the plurality of second connection pads.

9. The substrate structure of claim 1, wherein the first circuit build-up layer and the second circuit build-up layer respectively have a first curved shape and a second curved shape facing in different directions.

10. The substrate structure of claim 1, wherein the first circuit build-up layer and the second circuit build-up layer respectively have a first curved shape and a second curved shape facing in the same direction.

11. A method of manufacturing a substrate structure, comprising:
providing a core layer having a first side, a second side opposite to the first side, a plurality of first connection pads and a plurality of second connection pads, wherein the plurality of first connection pads and the plurality of second connection pads are formed on the first side and the second side respectively;
bonding a plurality of first bonding pads of a first circuit build-up layer to the plurality of first connection pads of the core layer, wherein the first circuit build-up layer is located on the first side of the core layer, and a first gap is formed between the first side of the core layer and the first circuit build-up layer; and
bonding a plurality of second bonding pads of a second circuit build-up layer to the plurality of second connection pads of the core layer, wherein the second circuit build-up layer is located on the second side of the core layer, and a second gap is formed between the second side of the core layer and the second circuit build-up layer.

12. The method of claim 11, wherein a first circuit sub-layer of the first circuit build-up layer and a second circuit sub-layer of the second circuit build-up layer are first formed when forming the first circuit build-up layer and the second circuit build-up layer, a third circuit sub-layer and a fourth circuit sub-layer of the first circuit build-up layer are respectively built up, stacked, or symmetrically formed on opposite sides of the first circuit sub-layer, and a fifth circuit sub-layer and a sixth circuit sub-layer of the second circuit build-up layer are respectively built up, stacked, or symmetrically formed on opposite sides of the second circuit sub-layer, a seventh circuit sub-layer and an eighth circuit sub-layer of the first circuit build-up layer are respectively built up, stacked, or symmetrically formed on the third circuit sub-layer and the fourth circuit sub-layer, and a ninth circuit sub-layer and a tenth circuit sub-layer of the second circuit build-up layer are respectively built up, stacked, or symmetrically formed on the fifth circuit sub-layer and the sixth circuit sub-layer.

13. The method of claim 11, wherein a number of circuit sub-layers of the first circuit build-up layer is the same as a number of circuit sub-layers of the second circuit build-up layer.

14. The method of claim 11, wherein a number of circuit sub-layers of the first circuit build-up layer is different from a number of circuit sub-layers of the second circuit build-up layer.

15. The method of claim 11, further comprising forming a first cladding layer in the first gap between the first side of the core layer and the first circuit build-up layer to cover the plurality of first connection pads and the plurality of first bonding pads, and forming a second cladding layer in the second gap between the second side of the core layer and the second circuit build-up layer to cover the plurality of second connection pads and the plurality of second bonding pads.

16. The method of claim 11, further comprising forming a first insulating protective sub-layer having a plurality of first openings on an outermost circuit sub-layer of the first circuit build-up layer, and forming a second insulating protective sub-layer having a plurality of second openings on an outermost circuit sub-layer of the second circuit build-up layer.

17. The method of claim 11, wherein the plurality of first bonding pads of the first circuit build-up layer are connected to the plurality of first connection pads of the core layer via a plurality of first conductors, and the plurality of second bonding pads of the second circuit build-up layer are connected to the plurality of second connection pads of the core layer via a plurality of second conductors.

18. The method of claim 11, wherein the plurality of first connection pads, the plurality of second connection pads, the plurality of first bonding pads and the plurality of second bonding pads are all made of metal material, wherein the metal material of the plurality of first bonding pads is directly bonded to the metal material of the plurality of first connection pads, and the metal material of the plurality of second bonding pads is directly bonded to the metal material of the plurality of second connection pads.

19. The method of claim 11, wherein the first circuit build-up layer and the second circuit build-up layer respectively have a first curved shape and a second curved shape facing in different directions.

20. The method of claim 11, wherein the first circuit build-up layer and the second circuit build-up layer respectively have a first curved shape and a second curved shape facing in the same direction.
